(19) United States
(12) Patent Application Publication
(10) Pub. No.: US 2021/0384920 A1
(43) Pub. Date: Dec. 9, 2021

(54) METHOD FOR LAYERED ENCODING UNDER HIGH DIMENSIONAL MODULATION

(71) Applicant: HANGZHOU ZEMINGRUI EQUITY INVESTMENT CO.,LTD., Hangzhou (CN)

(72) Inventor: Xinmei WANG, Hangzhou (CN)

(21) Appl. No.: 17/390,423

(22) Filed: Jul. 30, 2021

Related U.S. Application Data
(63) Continuation of application No. PCT/CN2019/096925, filed on Jul. 19, 2019.

(30) Foreign Application Priority Data
Jul. 15, 2019 (CN) 201910635604.6

(51) Int. Cl. H03M 13/35; H04L 1/00; H03M 9/00

(52) U.S. Cl. CPC H03M 13/353; H03M 9/00; H04L 1/0059

(57) ABSTRACT

A layered coding method based on high order modulation comprising: S1: inputting serial data flow from a serial data input end into a serial-to-parallel converter; S2: inputting the data flow treated by the serial-to-parallel converter into the a multi-layer coder; S3: correlating the coders at individual layers with each other and transmitting information based on high order modulation; S4: inputting the data flow treated by the coders at individual layers into a modulator for modulation mapping processing; S5: outputting the data flow from the output end of the modulator. By means of correlating coders at layers with each other, the coder at each layer can code the data of its own layer while transmitting the data to the coder at a higher layer for protection, until reaching the coder at the highest layer, improving the coding rate, error correcting ability and data processing performance in a multi-layer coder

### CROSS REFERENCE TO RELATED APPLICATIONS

This application is a continuation of PCT/CN2019/096925 filed 2019 Sep. 12, which claims priority to CN201910635604.6 filed 2019 Jul. 15, both of which are incorporated herein by reference.

### FIELD OF THE INVENTION

The present application relates to the field of communication coding technology, and in particular to a layered coding method based on high-order modulation.

### DESCRIPTION OF THE RELATED ART

In the field of digital communication, using an error correcting code to correct an error code generated during data transmission is a widely used error control technique. Usually, error correction coding comprises coding binary data, and the quality of the coding is determined by the Hamming distance in the code word set. Ungerboeck indicated in his precursory document that, in the case of high order modulation (in which one modulation symbol carries a plurality of bits of information data), the factor determining the quality of coding is not the Hamming distance, but the Euclidean distance, which is the actual distance in the transmission space of the signal after coding modulation. Ungerboeck proposed a coding method for improving the Euclidean distance of a modulated signal sequence by using redundant information obtained by improving the order of modulation, without increasing the system bandwidth.

In the case high order modulation, the data in different layers usually have different probability of transmission error. Generally, the data in a lower layer has a higher error probability. Therefore, a layered code scheme generally adopts coder having different intensity at different layers, that is, a coder having a higher intensity is used at a lower layer; due to which the layered coding is generally termed as unequal error protection code. However, it is difficult to balance the probability of error transmission at different layers so as to achieve the best performance of a system.

In view of this, the present application provided a new method of layered coding based on high order modulation, which can effectively balance the probability of transmission error at different layers to achieve the best performance of a system.

### BRIEF SUMMARY

The object of the present application is to provide a layered coding method based on high order modulation, which, by means of correlating coders at a plurality of layers with each other, can achieve equal coding rate at individual coders at the plurality of layers. The coder at each layer can code the data of its own layer while transmitting the data to the coder at a higher layer for protection, until reaching the coder at the highest layer, addressing the problems of low coding rate, poor error correcting ability and bad performance present in conventional multi-layer coders.

In order to address the above technical problem, the present application provides the following technical solution:

the present application provides a layered coding method based on high order modulation comprising the following steps:

Step S1: inputting serial data flow from a serial data input end into a serial-to-parallel converter;

Step S2: inputting the data flow treated by the serial-to-parallel converter into a multi-layer coder;

Step S3: correlating the coders at individual layers with each other and transmitting information based on high order modulation;

Step S4: inputting the data flow treated by the coders at individual layers into a modulator for modulation mapping processing;

Step S5: finally outputting the data flow from the output end of the modulator.

Preferably, in Step S1, the serial data input end is used for supplying serial data flow of data bit sequence; and the serial-to-parallel converter is used for converting the serial data flow of data bit sequence into a parallel data flow.

Preferably, in Step S2, the multi-layer coder comprises a base layer processor and at least one enhancement layer processor; and the enhancement layer processor comprises an enhancement layer coder and at least two reference processing units.

Preferably, in Step S3, in the multi-layer coder, a coder at a lower layer needs to code the data of its own layer, and sends the information of the coder to a coder at a higher layer; and the coder at a higher layer needs to code both the data of its own layer and the coding information of the lower layer and sends the information of the coder of its own layer to the coder at a further higher layer, until reaching the coder at the highest layer.

Preferably, the number of the layers of the multi-layer coder is no less than 3.

Preferably, the coder comprises a non-systematic convolutional coder and a systematic convolutional coder; and both the non-systematic convolutional coder and the systematic convolutional coder are expressed by an octal number.

Preferably, in Step 4, the modulation mapping processing is used for processing the data flow into a high frequency signal to perform signal transmission.

The present application provides the following beneficial effects:

In the present application, by means of correlating coders at a plurality of layers with each other, the coder at each layer can code the data of its own layer while transmitting the data to the coder at a higher layer for protection, until reaching the coder at the highest layer, improving the coding rate, error correcting ability and data processing performance in a multi-layer coder.

in the multi-layer coder of the present application, the coders at individual layers are not independent from each other, avoiding the previous rule that the coders at individual layer must have different coding intensity. Therefore, the coders at individual layers have the same coding rate and error correction ability, and the mutual information transmission reaches a natural balance between the coding ability at individual layers.

Of course, any one product embodying the present application will not need to achieve all the advantages at the same time.

### BRIEF DESCRIPTION OF THE DRAWINGS

For the purpose of more dearly explaining the technical solutions according to the embodiments of the present application, the attached drawings required for describing the embodiments will be briefly described. It is apparent that, the drawings as described below show only some of the embodiments of the present application, and other drawings based on these can be obtained by those skilled in the art without paying any inventive labor.

FIG. 1 shows the basic coding structure of layered coding based on high order modulation;

FIG. 2 shows a non-systematic convolutional coder with rate ½ (15,13) according to embodiment 1 of the present application;

FIG. 3 shows a systematic convolutional coder with rate ½ (15,13) according to embodiment 2 of the present application;

FIG. 4 shows a ((15, 13), 12, (15, 13)) non-systematic code according to embodiment 3 of the present application;

FIG. 5 shows a ((15, 13), 12, (15, 13)) systematic two-layer coder according to embodiment 3 of the present application;

FIG. 6 is a diagram showing the result of computer simulation of a two-layer coding scheme taking quaternary continuous phase 4CPFSK modulation as an example.

### DETAILED DESCRIPTION

The technical solutions according to the embodiments of the present application will be clearly and completely described below in connection with the drawings of the embodiments. It is apparent that, the embodiments as described are only part, but not all, of the embodiments of the present application. Based on the embodiments of the present application, all the other embodiments made by those skilled in the art without paying any creative labor shall fall within the scope of protection of the present application.

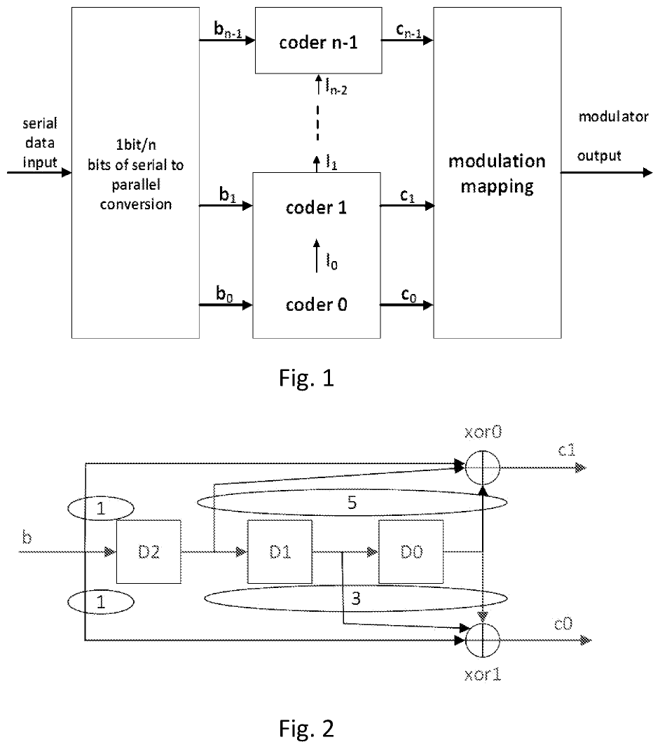

Referring to FIG. 1, the present application provides a layered coding method based on high order modulation, which comprises the following steps:

Step S1: inputting serial data flow from a serial data input end into a serial-to-parallel converter;

Step S2: inputting the data flow treated by the serial-to-parallel converter into a multi-layer coder;

Step S3: correlating the coders at individual layers with each other and transmitting information based on high order modulation;

Step S4: inputting the data flow treated by the coders at individual layers into a modulator for modulation mapping processing;

Step S5: finally outputting the data flow from the output end of the modulator.

In particular, in Step S1, the serial data input end is used for supplying serial data flow of data bit sequence; and the serial-to-parallel converter is used for converting the serial data flow of data bit sequence into a parallel data flow.

In particular, in Step S2, the multi-layer coder comprises a base layer processor and at least one enhancement layer processor; the enhancement layer processor comprises an enhancement layer coder and at least two reference processing units.

In particular, in Step S3, in the multi-layer coder, a coder at a lower layer needs to code the data of its own layer, and sends the information of the coder to a coder at a higher layer; and the coder at a higher layer needs to code both the data of its own layer and the coding information of the lower layer and sends the information of the coder of its own layer to the coder at a further higher layer, until reaching the coder at the highest layer.

In particular, the number of the layers of the multi-layer coder is no less than 3.

In particular, the coder comprises a non-systematic convolutional coder and a systematic convolutional coder; and both the non-systematic convolutional coder and the systematic convolutional coder are expressed by an octal number.

In particular, in Step 4, the modulation mapping processing is used for processing the data flow into a high frequency signal to perform signal transmission.

One particular application of the embodiments is as follows:

Embodiment 1

Referring to FIG. 2, 2 bits of output c1 and c0 are generated per 1 bit of input data b. Since the data input sequence is not originally reappeared in the output sequence of the coder, this code is called as non-systematic convolutional code. When the coding rate is increased, c1 and c0 will be canceled by following a certain rule. In FIG. 2. D2-D0 are 3-stage shift register, representing the adder of modulo 2 addition. Regarding a convolutional code, the error correction ability of the codes is decided by the number of stages of the register and the coding rate.

Generally, a convolutional coder can be expressed by octal numbers. Firstly, the connection relationship between the output end and input end of D2-D0 is observed, by which a point where there is a connection is marked as 1, and a point where there is no connection is marked as 0. Then, three points from right to left are grouped together, so that the connection relationship between xor0 and D2-D0 can be expressed by octal number 15. Similarly, the connection relationship between xor1 and D2-D0 can be expressed by octal number 13, and thus this coder can be expressed by (15, 13).

Embodiment 2

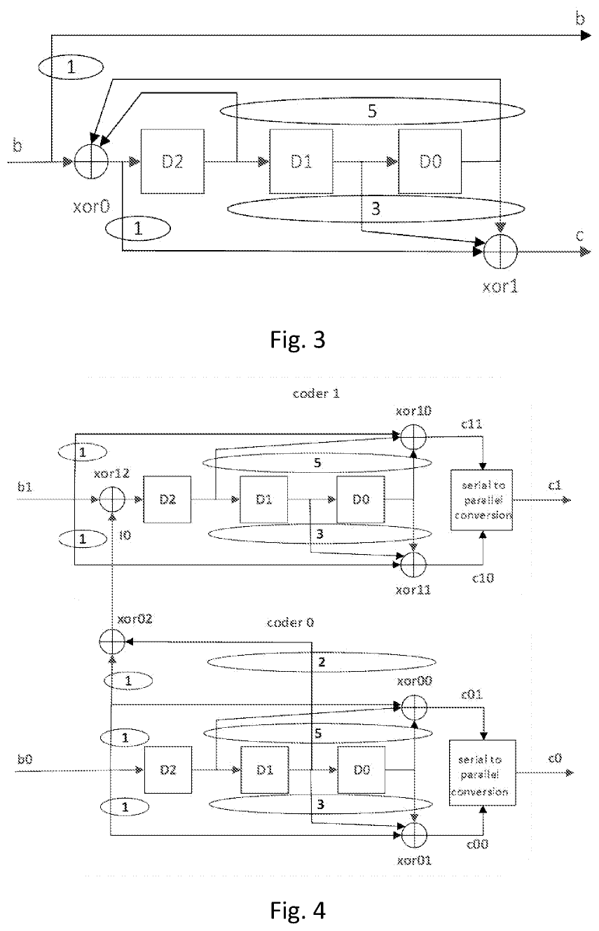

Referring to FIG. 3, a systematic convolutional coder with rate ½ is shown, in which the information bit after coding remains unchanged. Since the connection relationship between xor0 or xor1 and D2-D0 is the same as that in FIG. 2, the octal expression of the coder is the same as that of the coder in FIG. 2. When a higher coding rate is adopted, a certain number of check bit c can be canceled proportionally.

Embodiment 3

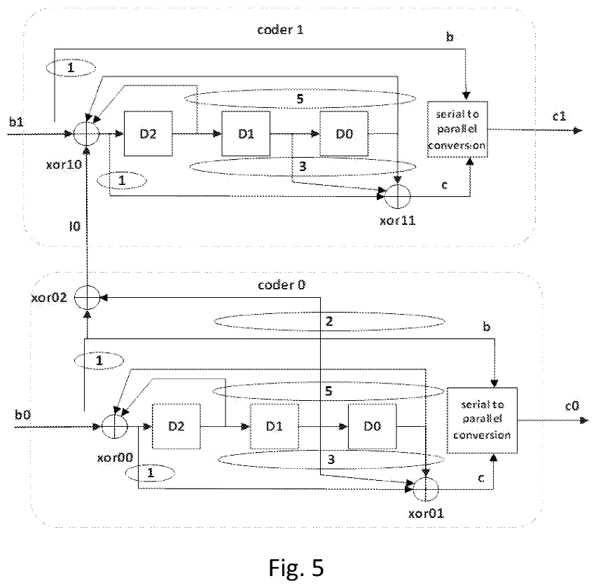

Referring to FIGS. 4-5, when a two-layer coding transmit information between coders, the two-layer coder is expressed by format (C0, I0; C1) in which C0 is the octal expression of the coder 0; I0 is the octal expression of the information transmitted by the coder 0; and C1 is the octal expression of the coder 1. The octal expression of I0 is made based on the same rule as that of the octal expression of the coder.

Embodiment 4

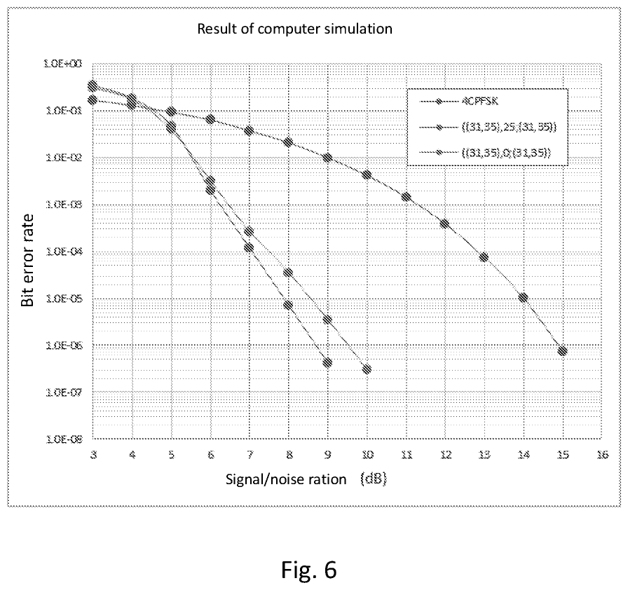

Referring to FIG. 6, a computer simulation was made to a two-layer coding scheme by taking quaternary continuous phase 4CPFSK modulation as an example. One 4CPFSK modulation symbol carrying two bits of digital information (m1m0) was given 4 values; the modulation mapping adopted {00, 01, 10, 11}→{−3, −1, +3, +1}. The modulation index was ¼. Firstly, a layered coder having appropriate Euclidean distance was selected. Non-systematic (31, 35) convolutional codes of a 4-stage register was used in the simulation, in which the coding rate of the two layers was ⅘. The two layers of convolutional codes having information transmission were ((3:1, 35), 25; (31, 35)). The 4CPFSK diagram in FIG. 6 is uncoded system. For the purpose of comparison, a coding scheme ((31, 35), 0; (31, 35)) having no information transmission was also simulated. Actually, the two-layer coding can adopt different coder;

It can be seen from the comparison in FIG. 6 that, when the signal/noise ratio is low, there is no significant effect in the information transmission between two-layer codes. The reason lies in that the ⅘ rate coding has no sufficient ability to the channel noise, and the upper layer code has no surplus ability that can be shared with the lower layer code. With the increase of the signal/noise ratio, the error code performance of the system having no information transmission is mainly decided by the bottom layer code. In this case, giving the surplus ability of the coder at a higher layer to a lower layer code can provide a good balance between the abilities of the two layer codes.

The simulation result shows that, the information transmission between multiple layers of codes has significant effect in improving the error code performance. When the modulation order is increased, this effect will be more significant. After a plurality of repeated experiments, in the case of quaternary continuous phase modulation, the non-systematic convolutional codes (13, 11), (31, 35), and (35, 35) and systematic convolutional codes (15, 6), (35, 15), and (21, 13) had the best Euclidean distance characteristics.

It is to be noted that, in the above system embodiments, individual units as included are only divided according to their logical functions, but they are not limited to the above way of dividing, as long as corresponding functions can be achieved; in addition, the particular names of individual function units are merely used for being distinguished from each other, but not intended for limiting the protection scope of the present application.

Additionally, those skilled in the art will understand that, part or all steps in the above embodiments can be completed by relevant hardware instructed by a program which can be stored in a computer readable storage medium.

The above preferred embodiments of the present application are disclosed merely for the purpose of helping understand the present application. The preferred embodiments do not fully describe all the details, and should not limit the present application to those particular implements. It is apparent that, a lot of modifications and changes can be made based on the present disclosure. These embodiments are selected and described for the purpose of better explaining the principle and actual use of the present application, so that those skilled in the art can thoroughly understand and make use of the present application. The present application is only limited by the claims and the full scope of protection and equivalents thereof.

What is claimed is:

1. A layered coding method based on high order modulation, characterized in comprising the following steps:
Step S1: inputting serial data flow from a serial data input end into a serial-to-parallel converter;
Step S2: inputting the data flow treated by the serial-to-parallel converter into a multi-layer coder;
Step S3: correlating the coders at individual layers with each other and transmitting information based on high order modulation;
Step S4: inputting the data flow treated by the coders at individual layers into a modulator for modulation mapping processing;
Step S5: finally outputting the data flow from the output end of the modulator.

2. The layered coding method based on high order modulation according to claim 1, characterized in that, in Step S1, the serial data input end is used for supplying serial data flow of data bit sequence; and the serial-to-parallel converter is used for converting the serial data flow of data bit sequence into a parallel data flow.

3. The layered coding method based on high order modulation according to claim 1, characterized in that, in Step S2, the multi-layer coder comprises a base layer processor and at least one enhancement layer processor; and the enhancement layer processor comprises an enhancement layer coder and at least two reference processing units.

4. The layered coding method based on high order modulation according to claim 1, characterized in that, in Step S3, in the multi-layer coder, a coder at a lower layer needs to code the data of its own layer; and sends the information of the coder to a coder at a higher layer; and the coder at a higher layer needs to code both the data of its own layer and the coding information of the lower layer and sends the information of the coder of its own layer to the coder at a further higher layer, until reaching the coder at the highest layer.

5. The layered coding method based on high order modulation according to claim 1, characterized in that, the number of the layers of the multi-layer coder is no less than 3.

6. The layered coding method based on high order modulation according to claim 1, characterized in that, the coder comprises a non-systematic convolutional coder and a systematic convolutional coder; and both the non-systematic convolutional coder and the systematic convolutional coder are expressed by an octal number.

7. The layered coding method based on high order modulation according to claim 1, characterized in that, in Step 4, the modulation mapping processing is used for processing the data flow into a high frequency signal to perform signal transmission.
